(19) United States
(12) Patent Application Publication
(10) Pub. No.: US 2025/0201762 A1
(43) Pub. Date: Jun. 19, 2025

(54) METHOD OF MANUFACTURING SEMICONDUCTOR PACKAGES

(71) Applicant: Samsung Electronics Co., Ltd., Suwon-si (KR)

(72) Inventors: Sungmin MOON, Suwon-si (KR); Pyoungwan KIM, Suwon-si (KR)

(73) Assignee: Samsung Electronics Co., Ltd., Suwon-si (KR)

(21) Appl. No.: 18/745,431

(22) Filed: Jun. 17, 2024

(30) Foreign Application Priority Data
Dec. 13, 2023 (KR) 10-2023-0180410

(51) Int. Cl. H01L 23/00; H01L 21/683; H01L 23/498

(52) U.S. Cl. CPC H01L 24/81; H01L 21/6835; H01L 23/49827; H01L 24/05; H01L 24/16; H01L 24/32; H01L 24/73; H01L 2221/68327; H01L 2221/68381; H01L 2224/05568; H01L 2224/16227; H01L 2224/32225; H01L 2224/73204; H01L 2224/81815; H01L 2224/83862

(57) ABSTRACT

Methods of manufacturing a semiconductor package may include providing an interposer substrate having first bonding pads on a first surface thereof and second bonding pads on a second surface thereof, the second surface opposite to the first surface; forming solder bumps the first bonding pads, respectively; applying a release layer on the solder bumps; forming a porous adhesive layer on the release layer, the porous adhesive layer defining a plurality of pores therein; attaching the porous release layer onto a carrier substrate using the porous adhesive layer; placing at least one semiconductor device on the second surface of the interposer substrate, the placed at least one semiconductor device having conductive bumps disposed on the second bonding pads; and performing a reflow process on the conductive bumps to mount the at least one semiconductor device on the second surface of the interposer substrate.

### CROSS-REFERENCE TO RELATED APPLICATION

This application claims priority benefit of under 35 U.S.C. § 119 to Korean Patent Application No. 10-2023-0180410, filed on Dec. 13, 2023 in the Korean Intellectual Property Office (KIPO), the disclosures of which are herein incorporated by reference in their entirety.

### BACKGROUND

### 1. Field

Example embodiments relate to methods of manufacturing a semiconductor package, for example methods of manufacturing a semiconductor package including different semiconductor devices stacked on a package substrate using an interposer.

### 2. Description of the Related Art

In conventional manufacture of a 2.5D semiconductor package, after performing a Wafer Supporting System (WSS) process to bond an interposer to a carrier substrate using an adhesive, a reflow process may be performed to mount a semiconductor device such as, for example, ASIC and/or HBM on the interposer. However, since the reflow process is performed at a high temperature, a release layer formed on, for example, a solder bump may be thermally decomposed, and a volume of the thermally decomposed release layer may expand. In such a case, as the thermally decomposed release layer exists in a gaseous state e, there may be a problem that the solder bump is liquefied by high temperature and/or deformed by the expansion pressure of the gas.

### SUMMARY

Example embodiments relate to methods of manufacturing a semiconductor package using an interposer while reducing or minimizing deformation of a solder bump.

In accordance with some example embodiments, a method of manufacturing a semiconductor package may compromise providing an interposer substrate, the interposer substrate having first bonding pads on a first surface thereof and second bonding pads on a second surface thereof, the second surface opposite the first surface; forming solder bumps on the first bonding pads, respectively; applying a release layer on the solder bumps; forming a porous adhesive layer on the release layer, the porous adhesive layer defining a plurality of pores therein; attaching the interposer substrate onto a carrier substrate using the porous adhesive layer; placing at least one semiconductor device on the second surface of the interposer substrate, the placing of the at least one semiconductor device including disposing conductive bumps on the second bonding pads; and performing a reflow process on the conductive bumps to mount the at least one semiconductor device on the second surface of the interposer substrate.

In accordance with some example embodiments, a method of manufacturing a semiconductor package may comprise providing an interposer substrate, the interposer substrate having first bonding pads formed on a first surface thereof and second bonding pads formed on a second surface thereof, the second surface opposite the first surface; forming solder bumps on the first bonding pads, respectively; forming a release layer, the release layer at least partially covering the solder bumps; applying an adhesive mixture on the release layer; applying heat to the adhesive mixture; thermally curing the adhesive mixture to vaporize an internal solvent thereof to form a porous adhesive layer, the porous adhesive layer defining a plurality of pores; attaching the interposer substrate onto a carrier substrate using the porous adhesive layer; placing at least one semiconductor device on the second surface of the interposer substrate, the placing the at least one semiconductor device including disposing conductive bumps of the at least one semiconductor device on the second bonding pads; and performing a reflow process on the conductive bumps to mount the at least one semiconductor device on the second surface of the interposer substrate.

In accordance with some example embodiments, a method of manufacturing a semiconductor package may comprise forming solder bumps are formed on a first surface of a substrate; forming a release layer on the first surface of the substrate, the release layer at least partially covering the solder bumps; applying an adhesive mixture on the release layer; applying heat to the adhesive mixture; thermally curing the adhesive mixture to vaporize an internal solvent thereof to form a porous adhesive layer, the porous adhesive layer defining a plurality of pores; attaching the substrate onto a carrier substrate using the porous adhesive layer; placing at least one semiconductor device on a second surface of the substrate, the placing the at least one semiconductor device including disposing conductive bumps of the at least one semiconductor device to bonding pads, the bonding pads being on the second surface of the substrate, the second surface of the substrate being opposite to the first surface; and performing a reflow process on the conductive bumps to mount the at least one semiconductor device on a second surface of the substrate.

Accordingly, when a reflow process is performed in a high-temperature environment to mount a semiconductor device on an interposer substrate via conductive bumps, gas generated by melting and vaporization of the release layer on the solder bump may be trapped in the pores defined by the porous adhesive layer or discharged to the outside through the pores. Thus, it may be possible to reduce or prevent the gas-induced expansion pressure from being applied to the solder bump and/or reduce or prevent the solder bump from solidifying in a deformed state, to thereby reduce a defect rate of the solder bump.

### BRIEF DESCRIPTION OF THE DRAWINGS

Example embodiments will be more clearly understood from the following detailed description taken in conjunction with the accompanying drawings. FIGS. 1 to 21 represent non-limiting, example embodiments as described herein.

FIGS. 1 to 20 are cross-sectional views illustrating a method of manufacturing a semiconductor package in accordance with example embodiments.

FIG. 21 is a graphs illustrating mechanical strength and permeability with respect to porosity of an adhesive layer.

### DETAILED DESCRIPTION OF EXAMPLE EMBODIMENTS

Hereinafter, example embodiments will be explained in detail with reference to the accompanying drawings.

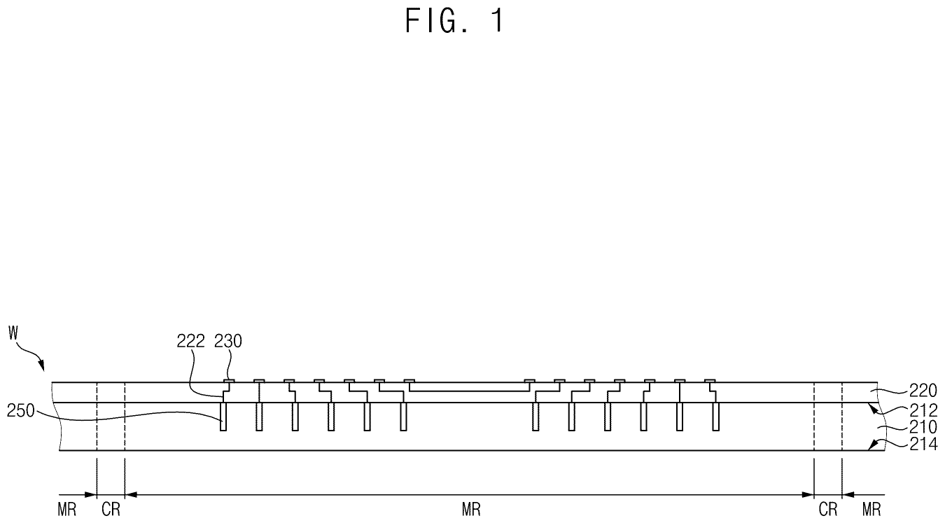

FIGS. 1 to 20 are views illustrating a method of manufacturing a semiconductor package in accordance with embodiments.

FIGS. 1, 2, 3, 4, 13, 14, 18, 19, and 20 are cross-sectional views illustrating a method of manufacturing a semiconductor package in accordance with embodiments.

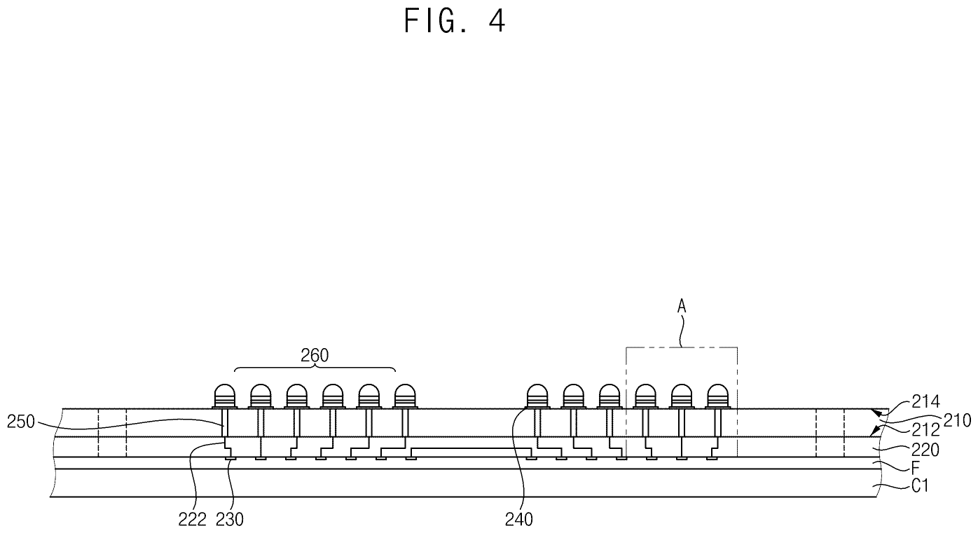

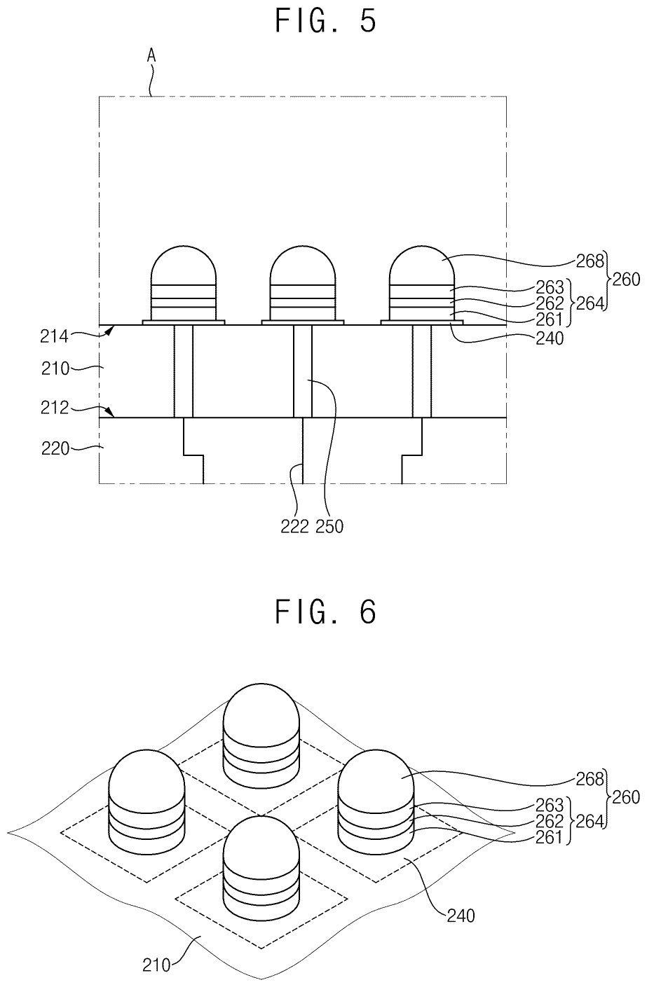

FIGS. 5, 7, 10, 11, and 12 are enlarged cross-sectional views illustrating portion ‘A’ of FIG. 4.

FIG. 6 is a perspective view illustrating bump structures of FIG. 5.

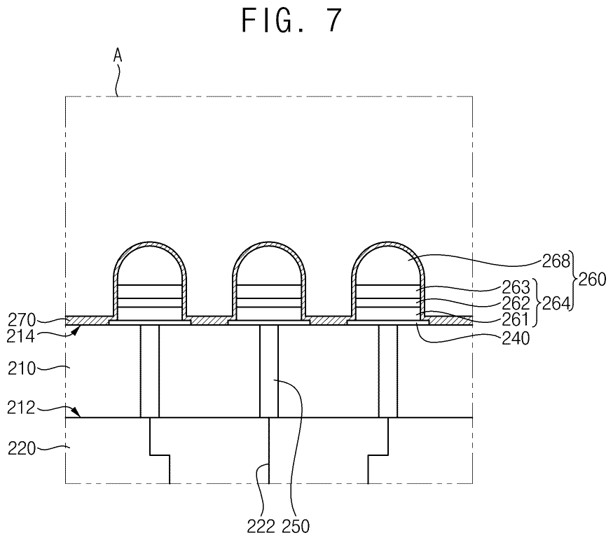

FIGS. 7 to 12 are views illustrating a process of forming a porous adhesive layer on a substrate.

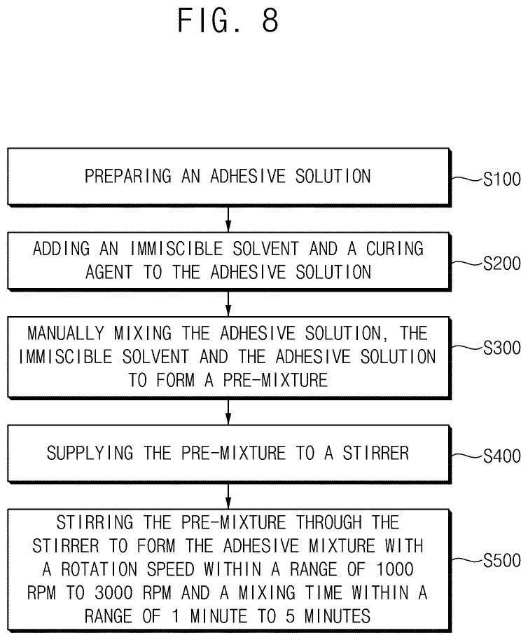

FIG. 8 is a flowchart illustrating a method of manufacturing an adhesive mixture.

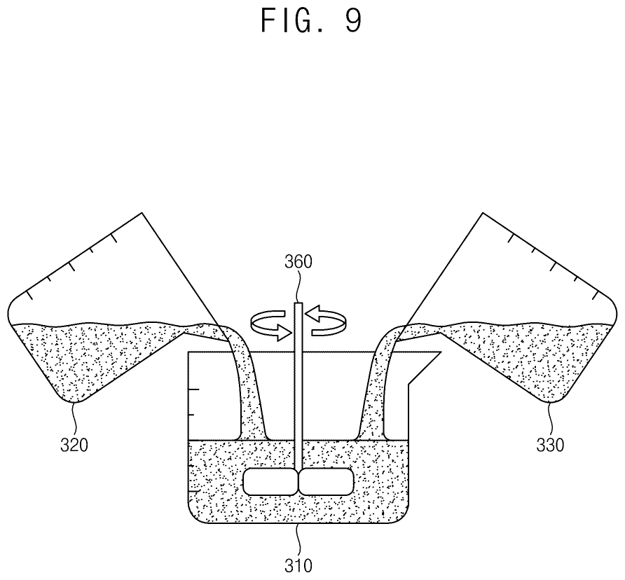

FIG. 9 is a view illustrating the method of manufacturing the adhesive mixture in FIG. 8.

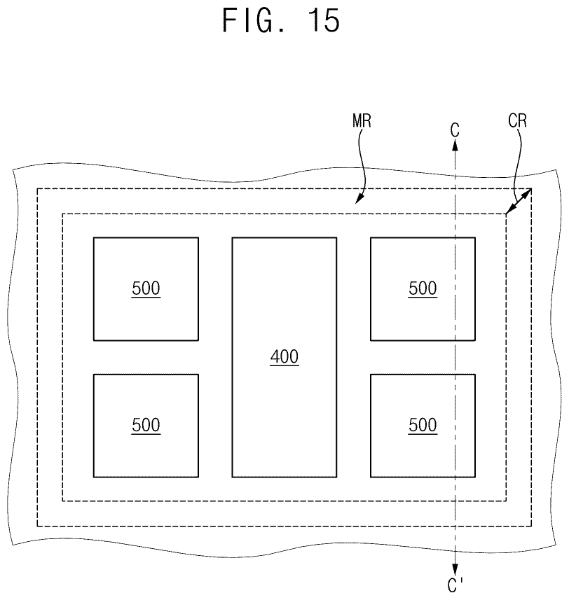

FIG. 15 is a plan view of FIG. 14. FIG. 14 is a cross-sectional view taken along the line C-C′in FIG. 15.

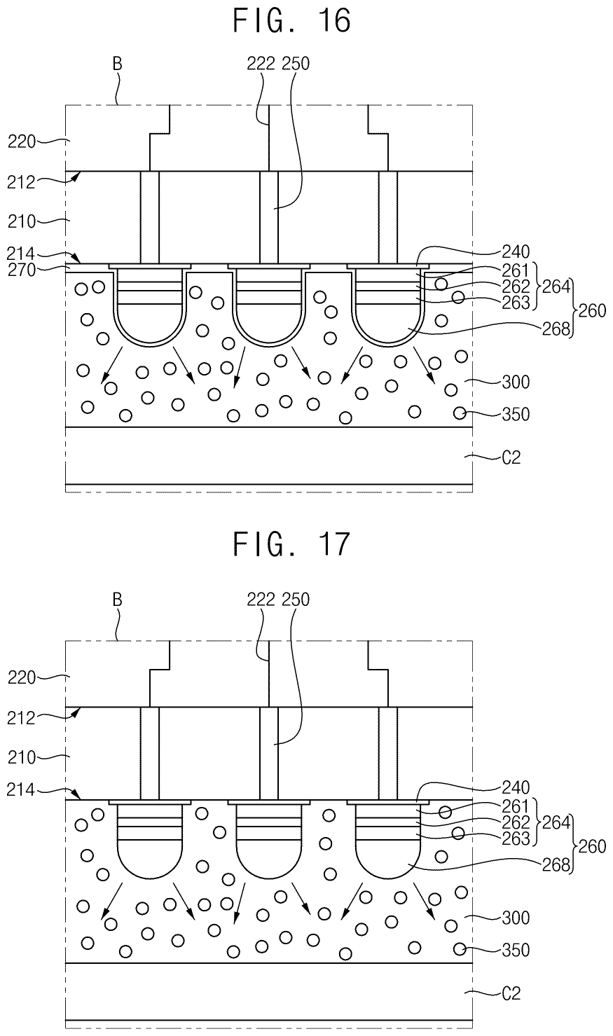

FIGS. 16 and 17 are enlarged cross-sectional views illustrating portion ‘B’ of FIG. 14. FIGS. 16 and 17 are cross-sectional views illustrating an inside of a porous adhesive layer during a reflow process for conductive bumps.

Referring to FIG. 1, a semiconductor wafer W for a base structure may be provided.

In some example embodiments, the base structure may include, for example, a silicon interposer die. Alternatively or additionally, the base structure may include, for example, a logic chip or a semiconductor die on which a memory chip is implemented, but example embodiments are not limited thereto.

The wafer W may include a substrate 210 and a wiring layer 220. The substrate 210 may have a first surface 212 and a second surface 214 opposite to the first surface 212. The wiring layer 220 may be provided on the first surface 212 of the substrate 210. The wafer W may include a package region, for example, a mounting region MR on which the semiconductor device(s) are mounted and a scribe lane region, for example, a cutting region CR surrounding the mounting region MR. As will be described below, the wafer W may be cut along the cutting region CR that divides the mounting region MR and may be individualized into an interposer 200. For example, the mounting region MR may have an area of about 20 mm×30 mm or more, but example embodiments are not limited thereto.

For example, the substrate 210 may include, for example, a semiconductor material such as silicon, germanium, silicon-germanium, etc., and/or a group III-V compound semiconductor such as gallium phosphide (GaP), gallium arsenic (GaAs), gallium antimonide (GaSb), etc. In some example embodiments, the substrate 210 may be or include a silicon-on-insulator (SOI) substrate or a germanium-on-insulator (GOI) substrate.

The wiring layer 220 may be formed on the first surface 212 of the substrate 210. The wiring layer 220 may be formed by, for example, a post-process called a back end of line (BEOL) process. The wiring layer 220 may include, for example, a plurality of insulating layers and a plurality of wirings 222 in the insulating layers. For example, the wirings may include a metal such as, for example, copper (Cu), but example embodiments are not limited thereto.

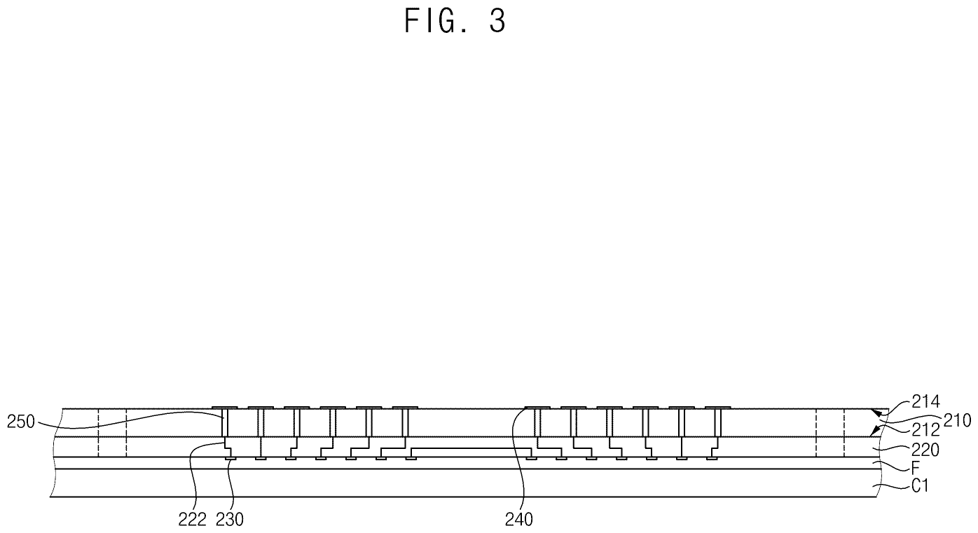

The substrate 210 may include a plurality of through-vias 250 formed through the substrate 210. The through-vias 250 may be electrically connected to the wirings 222, respectively. Through-vias 250 may be, for example, formed before polishing a backside surface of the substrate 210, for example, the second surface 214 (in other words, the through vias may be formed by via first and/or via middle processes). Alternatively, through-vias 250 may be formed after polishing the backside surface of the substrate 210 as illustrated in FIG. 3 (via last process).

A first bonding pad 230 may be provided on, for example, an outermost insulating layer of the wiring layer 220. The through-via 250 may be electrically connected to the first bonding pad 230 through the wiring 222.

Referring to FIGS. 3 to 6, a second bonding pad 240 may be formed on the second surface 214 of the substrate 210, and referring to FIGS. 4 to 6, a bump structure 260 may be formed on the second bonding pad 240 as, for example, a conductive connection member.

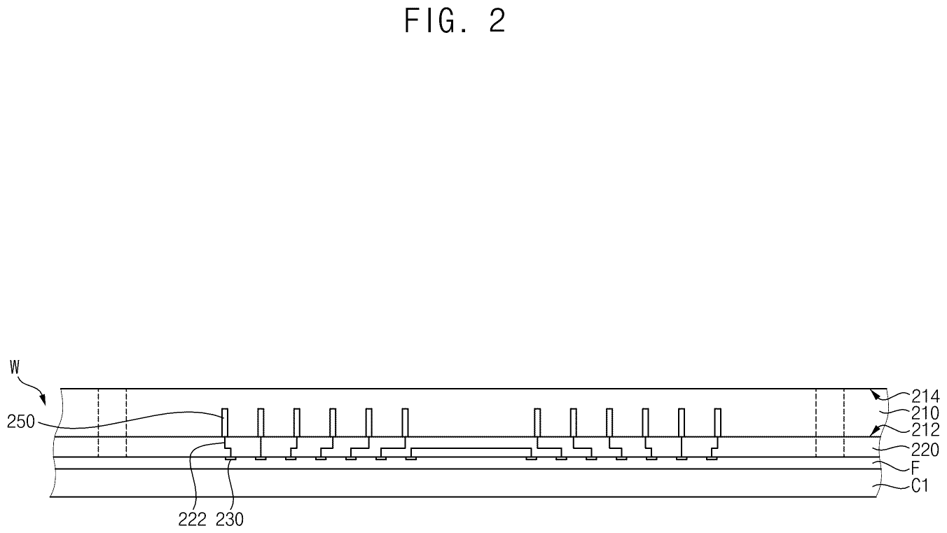

Referring to in FIGS. 2 and 3, the backside surface of the substrate 210, for example the second surface 214, may be polished by using a substrate support system WSS (not shown). After the wafer W is attached onto a first carrier substrate C1 by using an adhesive layer F, the second surface 214 of the substrate 210 may be partially removed until, for example, a portion of the through-via 250 is exposed (not shown).

The second surface 214 of the substrate 210 may be partially removed by, for example, a grinding process such as, for example, a chemical mechanical polishing (CMP) process, but example embodiments are not limited thereto. Accordingly, a thickness of the substrate 210 may be reduced to a desired thickness. For example, the substrate 210 may have a thickness in a range of about 50 μm to about 200 μm. Additionally, one end portion of the through-via 250 may be exposed from (for example, may not overlap with) the second surface 214 of the substrate 210.

As illustrated in FIGS. 4 to 6, a second bonding pad 240 may be formed on the second surface 214 of the substrate 210 to be electrically connected to the through-via 250, and a bump structure 260 may be formed on the second bonding pad 240.

A seed layer and a photoresist layer may be formed on the second surface 214 of the substrate 210, an exposure process may be performed on the photoresist layer to form a photoresist pattern having an opening that exposes a portion of the seed layer, and then a plating process may be performed on the seed layer to form the second bonding pad 240.

For example, the second bonding pad 240 may have a diameter of about 70 to about 80 μm. The diameter of the second bonding pad 240 may be, for example, about at least three times a diameter of the first bonding pad 230, but example embodiments are not limited thereto.

As illustrated in, for example, FIGS. 5 and 6, the bump structure 260 may be formed on the second bonding pad 240. The bump structure may include a pillar bump 264 having a circular, ovoid, annular, or similar shape and a solder bump 268 formed on the pillar bump 264. The pillar bump 264 may include, for example, first to third plating pattern layers 261, 262, and 263 sequentially stacked.

In more detail, a seed layer may be formed on the second bonding pad 240 on the second surface 214 of the substrate 210, and a photoresist pattern, having an opening that exposes (for example, does not overlap with) a portion of the seed layer, may be formed on the second surface 214 of the substrate 210.

Then, the opening may be filled up with a conductive material to form the bump structure 260. For example, the first to third plating pattern layers 261, 262, and 263 may be sequentially formed and stacked in the opening, the solder bump 268 may be formed on the third plating pattern layer, and the photoresist pattern may be removed from the substrate 210 to form the bump structure 260. The first and third plating pattern layers may include, for example, copper (Cu), and the second plating pattern layer may include, for example, nickel (Ni), but example embodiments are not limited thereto. The solder bump 268 may include, for example, solder.

Then, the first carrier substrate C1 may be removed from the wafer W.

Referring to FIGS. 7 to 12, a release layer 270 may be formed on the substrate 210 and cover (for example, at least partially cover) the bump structure 260, and, referring to FIGS. 8 to 12, a porous adhesive layer 300 may be formed on the release layer 270.

As illustrated in FIG. 7, the release layer 270 may be formed on the second surface 214 of the substrate 210 and cover the bump structure 260. The release layer 270 may be formed by, for example, a chemical vapor deposition (CVD) process, but example embodiments are not limited thereto, and the formation of release layer 270 may include more of various processes or techniques. The material of the release layer may include, for example, a polymer-based material that may be thermally decomposed in a subsequent reflow process, but example embodiments are not limited thereto.

As illustrated in FIGS. 8 and 9, an adhesive mixture 340, obtained by mixing, for example, at least an adhesive solution 310, an immiscible solvent 320, and a curing agent 330, may be formed.

First, the adhesive solution 310 may be prepared (S100). The adhesive solution 310 may include, for example, a thermosetting polymer, but example embodiments are not limited thereto. For example, the adhesive solution may include a siloxane-based elastomer including polydimethylsiloxane (PDMS), etc., but example embodiments are not limited thereto.

Subsequently, one or more substances, for example immiscible solvent 320 and curing agent 330 may be added (for example, “supplied”) to the adhesive solution 310 (S200). When heat is applied to the adhesive solution, the curing agent 330 may serve to help the adhesive solution to be cure into a solid. The immiscible solvent 320 may include a solvent that is insoluble (for example, at least partially insoluble) or immiscible with the adhesive solution 310, which may be a hydrophobic solution. For example, the immiscible solvent 320 may include a hydrophilic solvent. For example, the immiscible solvent 320 may include, for example, water (H₂O), but example embodiments are not limited thereto. A boiling point of the immiscible solvent 320 may be, for example, lower than a thermal curing temperature of the adhesive solution 310. Accordingly, when heat is applied to cure the adhesive solution 310, the immiscible solvent 320 in the adhesive mixture 340 may vaporize (for example, evaporate) before complete curing of the adhesive solution.

A mixture ratio of the adhesive solution 310 and the immiscible solvent 320 may be in a range of about 1:1 to about 1:1000 based on a weight ratio. The structure, porosity, size, etc. of the pores formed in (for example, defined by or in) the porous adhesive layer 300 may be determined by adjusting the mixture ratio.

Then, the adhesive solution, the immiscible solvent, and the adhesive solution may be manually mixed to form a pre-mixture (S300), and then the pre-mixture may be supplied to a stirrer 360 (S400). The stirrer may include, for example, a centrifugal stirrer for stirring a solution by using a centrifugal force, but example embodiments are not limited thereto.

Then, the pre-mixture may be stirred through the stirrer to form the adhesive mixture 340 (S500). A rotation speed of the stirrer may be within a range of about 1000 rpm to about 3000 rpm. A mixing time of using the stirrer may be within a range of about 1 minute to about 5 minutes.

In some example embodiments, an amphiphilic substance may be additionally supplied to the adhesive mixture 340. The amphiphilic solvent may include, for example, a protic solvent such as ethanol, methanol, isopropyl alcohol (IPA), etc., but example embodiments are not limited thereto. The amphiphilic solvent may be or include, or example, a solvent exhibiting hydrophobicity and hydrophilicity, and when the adhesive solution 310 and the immiscible solvent 320 are stirred, the porosity of the porous adhesive layer 300 may be more freely controlled by increasing the degree of dispersion of the hydrophilic solvent.

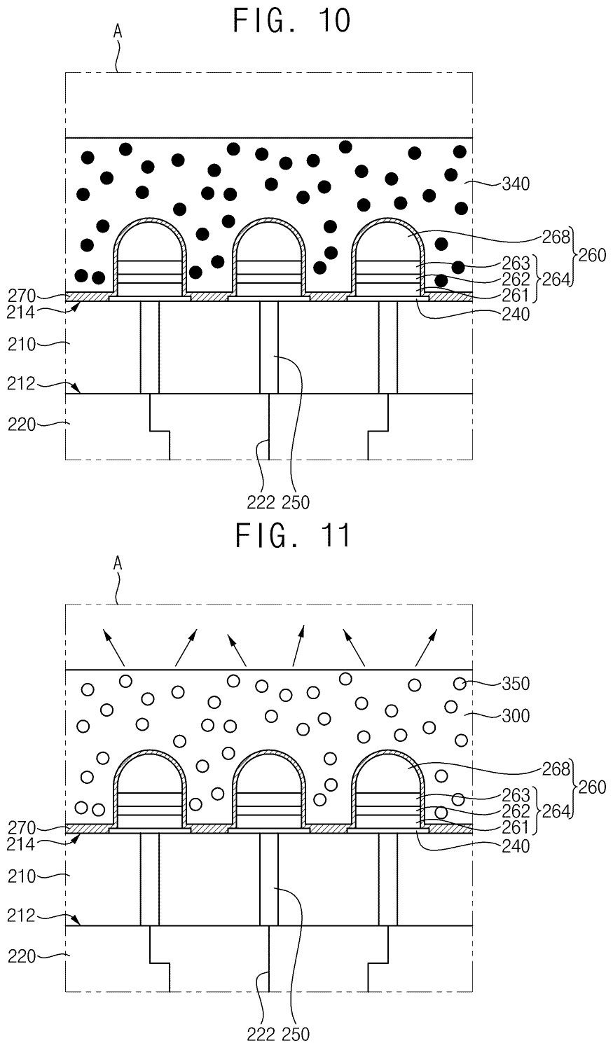

As illustrated in FIG. 10, the adhesive mixture 340 may be applied on the release layer 270. The adhesive mixture may be formed by, for example, a spin coating process, but example embodiments are not limited thereto, and may be formed using various coating methods.

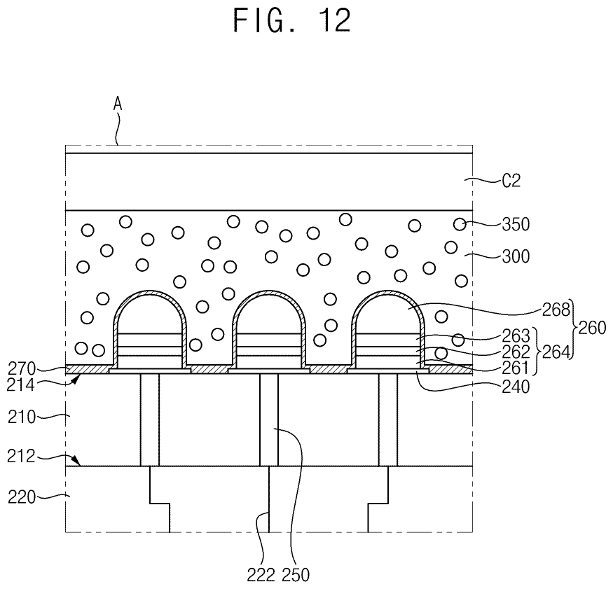

As illustrated in FIGS. 11 and 12, a baking process may be performed to thermally cure the adhesive mixture 340 to form the porous adhesive layer 300 having pores 350 therein. The baking process may be, for example, performed at a temperature of about 100° C. to 150° about C. The immiscible solvent 320 in the adhesive mixture 340 may be vaporized by the baking process. The vaporized immiscible solvent 320 may have a low density and thus may rise to an upper portion of the adhesive mixture 340 and be discharged to the outside. In this process, the adhesive solution 310 may be thermally cured and solidified into a solid. Thus, the path through which the vaporized immiscible solvent 320 may pass may remain as a trace, and a plurality of pores 350 may be formed in the adhesive to form the porous adhesive layer 300.

Individual pores of plurality of pores 350 may be, for example, formed (for example, defined) to be connected to (for example, continuous or intercommunicating with) each other. Accordingly, gas (for example, vapor) generated in the porous adhesive layer 300 may be discharged to the outside of the porous adhesive layer 300 through the plurality of pores 350, and thus the porous adhesive layer 300 having (for example, defining) the plurality of pores 350 formed (for example, defined) therein may be formed on the substrate 210.

Sizes of the plurality of pores 350 in the porous adhesive layer 300 may be determined through a mixture ratio of the adhesive solution 310 and the immiscible solvent 320 of the adhesive mixture 340. The mixture ratio may be in a range of about 1:14 to about 4:11 based on volume. As the volume proportion of the immiscible solvent 320 increases, the size the pores 350 and porosity of may increase.

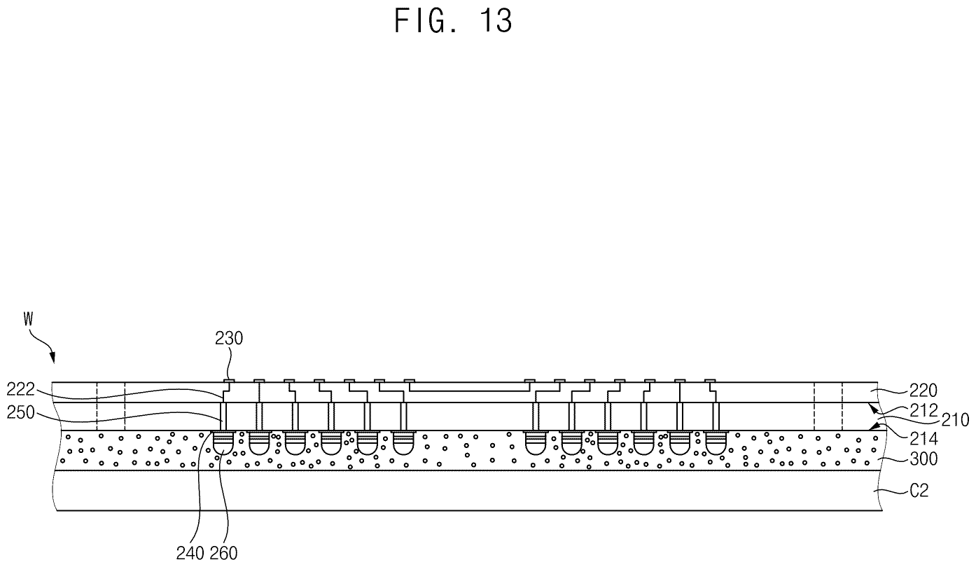

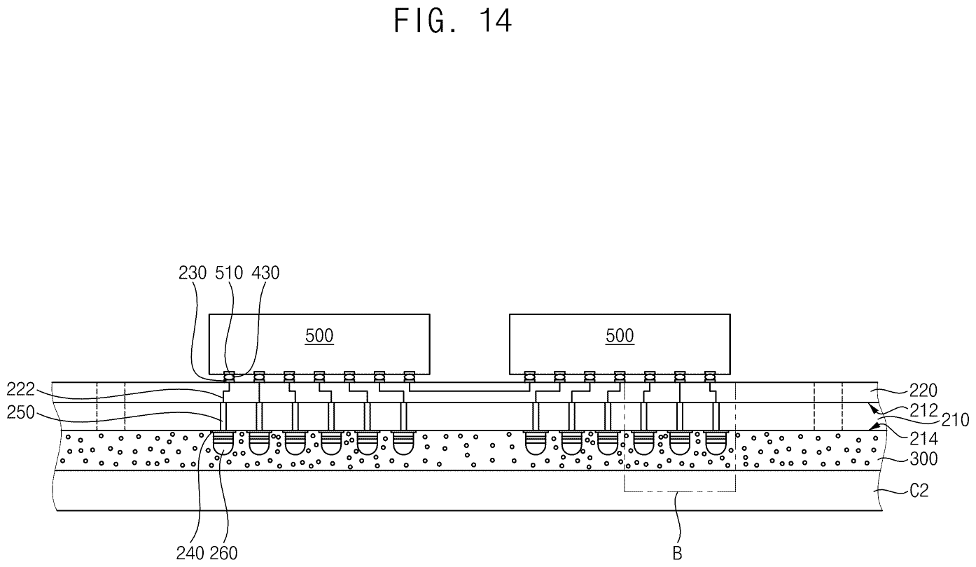

Referring to FIG. 13, after reversing (stated differently, turning upside down) the structure of FIG. 12, the wafer W may be adhered onto a second carrier substrate C2 by using the porous adhesive layer 300. The wafer W may be adhered onto the carrier substrate C2 such that at least one of the first bonding pads 230 is at least partially exposed.

Referring to FIGS. 14 and 15, conductive bumps 430 may be formed on first chip pads of a first semiconductor device 400 and second chip pads 510 of second semiconductor device 500, which may be in the form of a plurality, and then the first semiconductor device 400 and the second semiconductor device 500 may be disposed on the wiring layer 220 by the conductive bumps 430 (for example, disposed on the wiring layer 220 with the conductive bumps 430 therebetween).

As illustrated in FIG. 15, for example, the first semiconductor device 400 and the second semiconductor devices 500 may be disposed on the wiring layer 220 to be spaced apart from each other. The first semiconductor device 400 may be disposed at a central portion of the mounting region MR, and the second semiconductor devices 500 may be disposed on both sides of the first semiconductor device 400 to be adjacent to corner portions of the mounting region MR, respectively.

In some example embodiments, the first and second semiconductor devices may be mounted on the wiring layer 220 by a flip-chip bonding method. The first chip pads of the first semiconductor device 400 may be electrically connected to the first bonding pads 230 of the wiring layer 220 by the conductive bumps 430. The second chip pads 510 of the second semiconductor device 500 may be electrically connected to the second bonding pads 240 and/or the first bonding pads 230 of the wiring layer 220 by the conductive bumps 430

For example, the first semiconductor device 400 may include, for example, a logic semiconductor device, and the second semiconductor device 500 may include, for example a memory device, but example embodiments are not limited thereto. The logic semiconductor device may be, for example, an ASIC as a host such as CPU, GPU, and SoC. The memory device may include, for example, a high bandwidth memory (HBM) device. In such a case, the second semiconductor device may, for example, include a buffer die and a plurality of memory dies (chips) sequentially stacked on the buffer die. The buffer die and the memory dies may be electrically connected to each other by through silicon vias.

Referring to FIGS. 16 and 17, a reflow process may be performed on the conductive bumps 430 to mount the first semiconductor device 400 and the second semiconductor device 500 on the wafer W. For example, the reflow process may be performed at a temperature of about 220° C. to about 250° C.

As illustrated in FIG. 16, the release layer 270 may at least partially melt and vaporize during the reflow process. The gas generated by vaporization of the release layer 270 may move to and/or through the plurality of pores 350. For example, some of the gas may be discharged to the outside through the plurality of pores that connected to each other. Some of the gas may stay in the plurality of pores.

Accordingly, as illustrated in FIG. 17, gas generated by vaporization of the release layer 270 during the reflow process may be discharged through the plurality pores and may not apply expansion pressure (for example, substantial expansion pressure) to the solder bump 268 of the bump structure 260, such that the solder bump 268 can be maintained in its original shape, or shape substantially similar to its original shape, without being damaged or substantially.

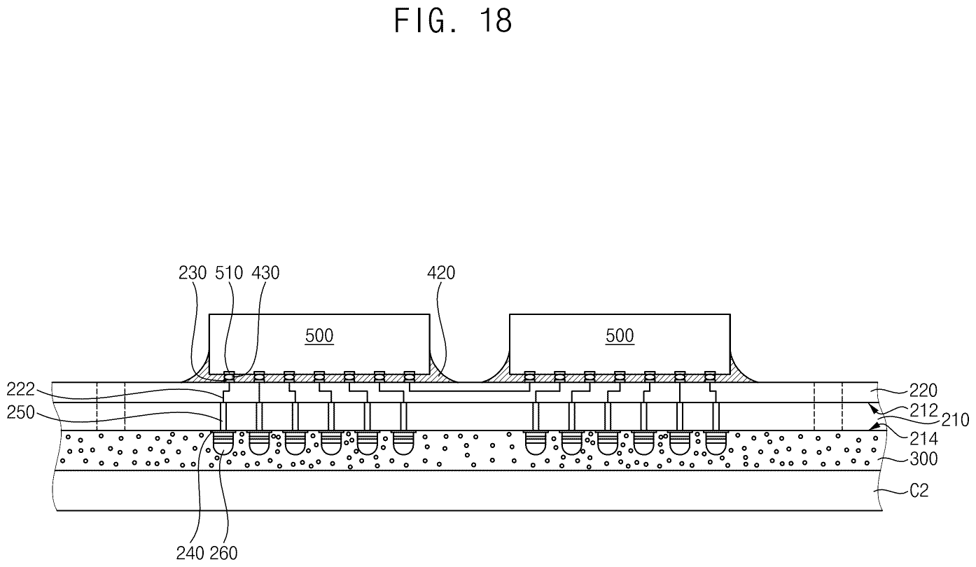

Referring to FIG. 18, an underfill member 420 may be formed between the first semiconductor device 400 and the wiring layer 220, between the second semiconductor device(s) 500 and the wiring layer 220, and/or between first semiconductor device 400 and semiconductor device(s) 500. For example, the underfill member 420 may fill or at least partially fill a space between (for example, defined or at least partially defined by) first semiconductor device 400, the second semiconductor device(s) 500, and the first wiring layer 220. The underfill member may be in the form of a plurality.

The underfill member may include, for example, a material having relatively high fluidity to effectively fill a space between the first and second semiconductor devices and the wiring layer 222. For example, individual ones of the underfill members may include, for example, an adhesive including an epoxy material, but example embodiments are not limited thereto.

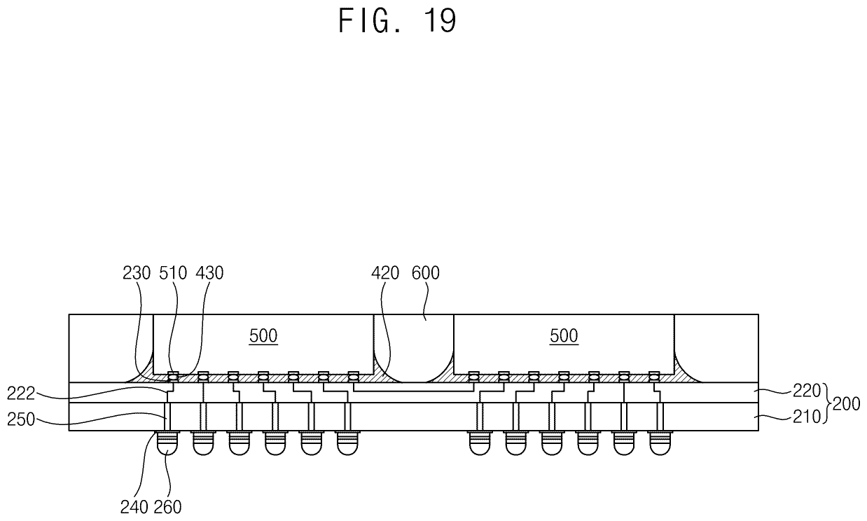

Referring to FIG. 19, a sealing member 600 covering (for example, at least partially covering) at least portions of the first semiconductor device 400 and the second semiconductor device 500 may be formed on the wiring layer 220.

In some example embodiments, after forming sealing member 600 covering (for example, at least partially covering) the first and/or second semiconductor devices 400 and 500 on the wiring layer 220, the sealing member may be partially removed to expose (for example, at least partially expose) upper surfaces of the second semiconductor devices 500.

The upper surfaces of the second semiconductor devices 500 may be exposed from (for example, not overlap with) the sealing member 600. An upper surface of the sealing member 600 may be, for example, coplanar with the upper surface of the second semiconductor device 500. The upper surfaces and side surfaces of the wiring layer and/or substrate 210 may be covered (for example, at least partially covered) by the sealing member 600.

Then, the substrate 210 and the porous adhesive layer 300 may be separated from the wafer W, and then the wafer W may be cut along the cutting area CA to form an individual interposer 200.

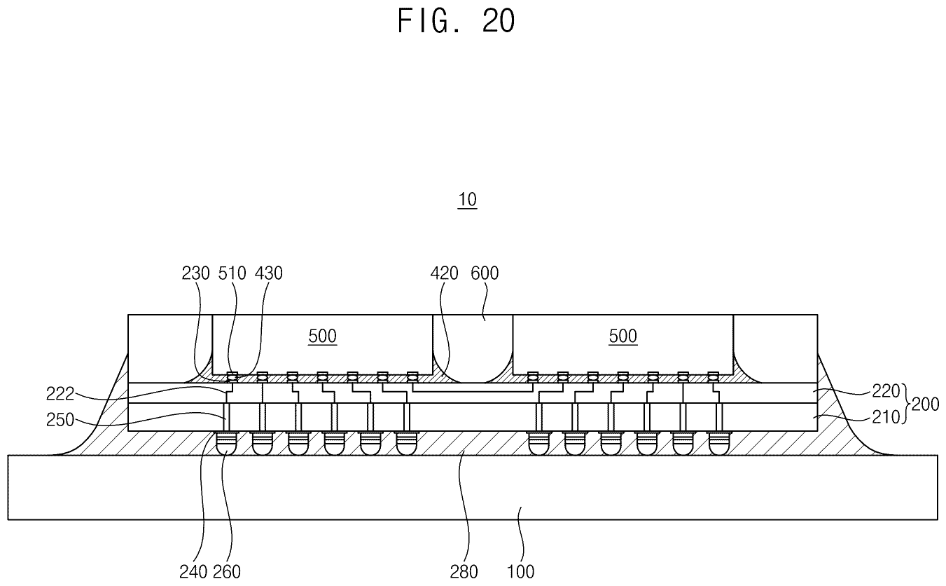

Referring to FIG. 20, the interposer 200, on which the first and second semiconductor devices 400 and 500 are mounted, may be disposed on the package substrate 100. Subsequently, a second underfill member 280 may be formed on the package substrate 100 and/or interposer 200, for example between the interposer 200 and the package substrate 100.

In some example embodiments, the interposer 200 may be mounted on the package substrate 100 through the bump structures 260. The interposer 200 may be attached to the package substrate 100 by, for example, a thermal compression process, but example embodiments are not limited thereto.

Then, external connection members such as, for example, solder balls, may be formed on the external connection pads on a lower surface of the package substrate 100 to complete a semiconductor package 10.

Hereinafter, the size and porosity of pores in the adhesive layer in accordance with some example embodiments will be described.

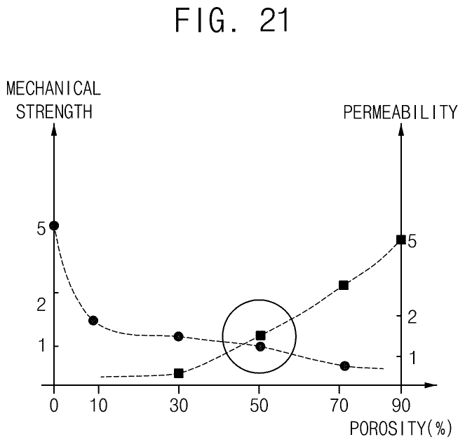

FIG. 21 is a graph illustrating mechanical strength and transmittance in accordance with porosity of the adhesive.

Referring to FIG. 21, as the porosity of the porous adhesive layer increases, the mechanical strength of the porous adhesive layer may decrease and the air permeability of the porous adhesive layer may increase. The porosity may be calculated from the volume of the pores and the volume of the material. The porosity may be calculated by Equation (1) below.

$$n = \frac{{V}_{p}}{{V}_{total}} \times 1 \; 00 ( \% ) \qquad Equation ( 1 )$$

Here, n is the porosity, Vp is the volume of the pores, and Vtotal is the total volume of the material.

The permeability can be calculated from the amount of air transmitted through the porous layer and the area of the porous layer. The permeability can be calculated by Equation (2) below.

$$P = \frac{{V}_{air flow}}{A} \qquad Equation ( 2 )$$

Here, P is a transmittance, Vair flow is a transmittance per unit time, and A is a unit area.

As the respective sizes of the pores increase, the connection (for example, intercommunication, networking, or allowance of passage or flow) between the plurality of pores may increases, and thus transmittance may be increased, thereby facilitating gas discharge. However, when sizes of the pores increases, the mechanical strength of the porous adhesive layer 300 may decrease. When the mechanical strength of the porous adhesive layer 300 decreases, an adhesive residue may remain on the wafer when the porous adhesive layer 300 is removed from the wafer W. Also, when the mechanical strength of the porous adhesive layer 300 decreases, the adhesion between the wafer W and the carrier substrate may decrease, and thus the reliability of the process may decrease.

Alternatively, when sizes of the pores decreases, the mechanical strength of the porous adhesive layer 300 increases, but the connection between the plurality of pores decreases In such a case, a passage or passages by which gas (which may include various gasses) generated in the porous adhesive layer 300 can be accommodated or discharged to the outside may not be effectively (for example, smoothly) generated, and thus transmittance may lowered, which may be disadvantageous in discharging gas. Thus, the porosity of the porous adhesive layer 300 may be determined at a level capable of effectively (for example, smoothly) discharging gas inside the porous adhesive layer to the outside while maintaining the adhesive force between the wafer W and the carrier substrate. For example, the porosity of the porous adhesive layer 300 may be in the range of about 40% to about 60%.

The semiconductor package may include semiconductor devices such as, for example, logic devices or memory devices. The semiconductor package may include, for example, logic devices such as central processing units (CPUs), main processing units (MPUs), or application processors (APs), etc, and volatile memory devices such as DRAM devices, HBM devices, or non-volatile memory devices such as flash memory devices, PRAM devices, MRAM devices, ReRAM devices, etc., but example embodiments are not limited thereto.

The foregoing is illustrative of example embodiments and is not to be construed as limiting thereof. Although a few example embodiments have been described, those ordinarily skilled in the art will readily appreciate that many modifications are possible in some example embodiments without materially departing from the novel teachings and advantages of the present inventive concepts. Accordingly, all such modifications are intended to be included within the spirit and scope of example embodiments as in the claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” may encompass both an orientation of above and below. The device may be otherwise oriented (rotated 90 degrees or at other orientations) and the spatially relative descriptors used herein interpreted accordingly.

What is claimed is:

1. A method of manufacturing a semiconductor package, the method comprising:
providing an interposer substrate, the interposer substrate having first bonding pads on a first surface thereof and second bonding pads on a second surface thereof, the second surface opposite the first surface;
forming solder bumps on the first bonding pads, respectively;
applying a release layer on the solder bumps;
forming a porous adhesive layer on the release layer, the porous adhesive layer defining a plurality of pores therein;
attaching the interposer substrate onto a carrier substrate using the porous adhesive layer;
placing at least one semiconductor device on the second surface of the interposer substrate, the placed the at least one semiconductor device having conductive bumps disposed on the second bonding pads; and
performing a reflow process on the conductive bumps to mount the placed at least one semiconductor device on the second surface of the interposer substrate.

2. The method of claim 1, further comprising:
disposing the interposer substrate on a package substrate.

3. The method of claim 1, wherein the forming the porous adhesive layer comprises:
applying an adhesive mixture;
applying heat to the adhesive mixture; and
thermally curing the adhesive mixture to vaporize an internal solvent to form the porous adhesive layer.

4. The method of claim 3, wherein applying the adhesive mixture includes preparing an adhesive solution;
supplying one or more substances to the adhesive solution, the one or more substances including an immiscible solvent and a curing agent; and
stirring the adhesive solution supplied with the one or more substances to form the adhesive mixture.

5. The method of claim 4, wherein a mixture ratio of the adhesive solution to the immiscible solvent is within a range of 1:14 to 4:11.

6. The method of claim 4, wherein the adhesive solution includes a thermoplastic elastomeric material.

7. The method of claim 4, wherein the adhesive solution includes a hydrophobic solution.

8. The method of claim 4, wherein a boiling point of the immiscible solvent is lower than a thermosetting temperature of the adhesive solution.

9. The method of claim 4, wherein the immiscible solvent comprises includes a hydrophilic solvent.

10. The method of claim 4, wherein the one or more substances supplied to the adhesive solution includes an amphiphilic solvent.

11. A method of manufacturing semiconductor package, the method comprising:
providing an interposer substrate, the interposer substrate having first bonding pads on a first surface thereof and second bonding pads on a second surface thereof, the second surface opposite the first surface;
forming solder bumps on the first bonding pads, respectively;
forming a release layer, the release layer at least partially covering the solder bumps;
applying an adhesive mixture on the release layer;
applying heat to the adhesive mixture;
thermally curing the adhesive mixture to vaporize an internal solvent thereof to form a porous adhesive layer, the porous adhesive layer defining a plurality of pores therein;
attaching the interposer substrate onto a carrier substrate using the porous adhesive layer;
placing at least one semiconductor device on the second surface of the interposer substrate, the placed at least one semiconductor device having conductive bumps disposed on the second bonding pads; and
performing a reflow process on the conductive bumps to mount the placed at least one semiconductor device on the second surface of the interposer substrate.

12. The method of claim 11, further comprising:
disposing the interposer substrate on a package substrate.

13. The method of claim 11, wherein the applying an adhesive mixture includes preparing an adhesive solution;
supplying one or more substances to the adhesive solution, the one or more substances including an immiscible solvent and a curing agent;
stirring the adhesive solution supplied with the one or more substances to form the adhesive mixture.

14. The method of claim 13, wherein a mixture ratio of the adhesive solution and the immiscible solvent is within a range of 1:14 to 4:11.

15. The method of claim 13, wherein the adhesive solution includes a thermoplastic elastomeric material.

16. The method of claim 13, wherein the adhesive solution includes a hydrophobic solution.

17. The method of claim 13, wherein a boiling point of the immiscible solvent is lower than a thermosetting temperature of the adhesive solution.

18. The method of claim 13, wherein the immiscible solvent comprises includes a hydrophilic solvent.

19. The method of claim 13, wherein the one or more substances supplied to adhesive solution includes an amphiphilic solvent.

20. A method of manufacturing semiconductor package, the method comprising:
forming solder bumps on a first surface of a substrate;
forming a release layer on the first surface of the substrate, the release layer at least partially covering the solder bumps;
applying an adhesive mixture on the release layer;
applying heat to the adhesive mixture;
thermally curing the adhesive mixture to vaporize an internal solvent thereof to form a porous adhesive layer, the porous adhesive layer defining a plurality of pores therein;
attaching the substrate onto a carrier substrate using the porous adhesive layer;
placing at least one semiconductor device on a second surface of the substrate, the second surface opposite to the first surface and having bonding pads thereon, the placed at least one semiconductor device having conductive bumps disposed on the bonding pads; and
performing a reflow process on the conductive bumps to mount the at least one semiconductor device on a second surface of the substrate.
